(19) United States
(12) Patent Application Publication
(10) Pub. No.: US 2023/0230492 A1
(43) Pub. Date: Jul. 20, 2023

(54) DIGITAL AUDIO SYSTEM

(71) Applicants: Nagarjun Srinivasan, San Jose, CA (US); Shrey Malhotra, Littleton, CO (US)

(72) Inventors: Nagarjun Srinivasan, San Jose, CA (US); Shrey Malhotra, Littleton, CO (US)

(21) Appl. No.: 18/099,651

(22) Filed: Jan. 20, 2023

Related U.S. Application Data
(60) Provisional application No. 63/266,943, filed on Jan. 20, 2022.

(51) Int. Cl. G09B 5/06; H04R 1/02; H04R 1/08; G06V 20/40; G10H 1/00; G10H 1/053; G09B 15/02; G06F 16/635

(52) U.S. Cl. CPC G09B 5/065; H04R 1/025; H04R 1/08; G06V 20/40; G10H 1/0008; G10H 1/053; G10H 1/0083; G09B 15/023; G06F 16/637; H04R 2201/028; G10H 2240/175; G10H 2210/091; G10H 2250/311; G10H 2220/096; G10H 2220/116; G10H 2240/321; H03F 3/183

(57) ABSTRACT

A portable digital audio system for a musician. The digital audio system includes an amplifier for processing an audio signal from a musical instrument or microphone electronically connected to the digital audio system and a speaker for playing a sound associated with the audio signal processed by the amplifier. The portable digital audio system also includes an audio control system providing operational control of the digital audio system and a primary housing for supporting the amplifier, the audio control system, and the speaker. Further, the digital audio system has a touch screen display in electronic communication with the audio control system and supported by the primary housing.

### CROSS-REFERENCE TO RELATED APPLICATIONS

The present application is a conversion of U.S. Provisional application having U.S. Ser. No. 63/266,943, filed Jan. 20, 2022 which claims the benefit under 35 U.S.C. 119(e). The disclosure of which is hereby expressly incorporated herein by reference.

### STATEMENT REGARDING FEDERALLY SPONSORED RESEARCH OR DEVELOPMENT

Not applicable.

### BACKGROUND OF THE DISCLOSURE

### 1. Field of the Invention

The present disclosure is directed to a novel and integrated digital audio and music system (or rig) that can be used to teach, learn and play musical instruments. The system is integrated with an audio interface, computer processor, touch display, video camera and network paraphernalia that allows users to learn faster and enjoy the experience of learning an instrument. The system achieves this by providing an experience that keeps the user motivated. Moreover the digital audio system that can be used to access archived classes and live music training output as video, audio or 3D visualization. Users can learn music together in real-time without requiring additional setup. These music training sessions can directly be delivered to the accompanied computer processor and enables professional musicians and teachers to analyse performance and provide real-time feedback to their students.

The present disclosure is also directed to an integrated system architecture that allows real time digital audio processing such as but not limited to noise gate, distortion, overdrive, equalizer, filtering and playback of audio signals generated by a musical instrument.

### 2. Description of the Related Art

When a beginner starts to exercise playing a music instrument it is important to have high motivation. Usually, beginners have high motivation when first learning to play a musical instrument, but since repetitive practicing of tone sequences is required, and the progress in learning is usually slow, a beginner often loses the inner motivation and stops practicing. As a result, it has been estimated that 85% of people that start playing a music instrument quit before they reach a reasonable skill level. An object of the invention is to alleviate the problems and disadvantages relating to the known prior issues.

Currently, the de facto standard for beginners or amateur musicians (working professionals who cannot invest time into a professional class or degree) trying to get better is either Youtube videos or learning apps that give you exercises to play. Going the Youtube route, it then becomes one's responsibility to sift through all the noise in order to reach the ultimate goal (i.e. learning a particular song/getting better at an instrument). In order to really get results from free information such as that available on Youtube/blogs, etc, one really needs to know what to look for—which most beginners and amateurs do not. Being put in such a situation, it is easy to see how a person starting off learning an instrument can get quickly overwhelmed by the barrage of information thrown at them through that open gates of the internet.

The second route is using tutoring apps. These apps generally run on a phone, tablet or computer and can connect to/record your instrument. They then provide feedback on the “correctness” of your play. Although these apps do help an absolute beginner be able to pick up and play simple tunes on an instrument, it rarely helps when musicians reach their first wall. A wall is when a learner feels plateaued—when more input is not translating into improving as a musician.

Most working professionals who want to learn an instrument on the side usually do not have dreams of selling albums. But, they would like to play their favourite song when they are alone, play a popular song at a party or just jam with their musician friends. No solution today really targets the aspect of being able to help someone perform (either on stage, open mic or in their living room) a song or set. The apps do not really have the human touch that can teach you to overcome the first learning plateau. The free options such as Youtube/blogs overwhelm someone who doesn't know exactly what they're looking for with too much noise. And the paid course options do help filter the noise but do not provide the flexibility of just learning one song or one concept—the course is a bundle in itself.

Therefore, a need exists to build an out of the box music rig that lets you plug in various instruments and experience music creation in addition to reducing the effort and hassle of connecting audio interfaces, rerouting wires and cables to and from laptops for DAWs. Furthermore, a need exists for this rig for applications such as, but not limited to music learning, remote guidance, multiplayer playback, performance creation and more.

### SUMMARY OF THE DISCLOSURE

The present disclosure is directed to a portable digital audio system for a musician. The digital audio system includes an amplifier for processing an audio signal from a musical instrument or microphone electronically connected to the digital audio system and a speaker for playing a sound associated with the audio signal processed by the amplifier. The portable digital audio system also includes an audio control system providing operational control of the digital audio system and a primary housing for supporting the amplifier, the audio control system, and the speaker. Further, the digital audio system has a touch screen display in electronic communication with the audio control system and supported by the primary housing.

### BRIEF DESCRIPTION OF THE DRAWINGS

FIG. 1 depicts multiple views of one embodiment of a digital audio system. constructed in accordance with the present disclosure.

FIG. 1 depicts multiple views of one embodiment of a digital audio system. constructed in accordance with the present disclosure.

FIG. 2 shows additional details of the digital audio system shown in FIG. 1 and constructed in accordance with the present disclosure.

FIGS. 3A-3C are perspective views of the digital audio system constructed in accordance with the present disclosure.

FIG. 4 is perspective view of a portion of the digital audio system constructed in accordance with the present disclosure.

FIG. 5 is a diagramatic view of the electronic components of the digital audio system constructed in accordance with the present disclosure.

FIGS. 6-11 are screenshots from a video display of the digital audio system constructed in accordance with the present disclosure.

FIG. 12 is a diagram of a potential cloud architecture useable with a single (or multiple) digital audio systems constructed in accordance with the present disclosure.

### DETAILED DESCRIPTION OF THE DISCLOSURE

Those skilled in the art will appreciate that the logic and process steps illustrated in the various flow diagrams discussed below may be altered in a variety of ways. For example, the order of the logic may be rearranged, sub-steps may be performed in parallel, illustrated logic may be omitted, other logic may be included, etc. One will recognize that certain steps may be consolidated into a single step and that actions represented by a single step may be alternatively represented as a collection of sub-steps. The figures are designed to make the disclosed concepts more comprehensible to a human reader. Those skilled in the art will appreciate that actual data structures used to store this information may differ from the figures and/or tables shown, in that they, for example, may be organized in a different manner; may contain more or less information than shown; may be compressed, scrambled and/or encrypted; etc.

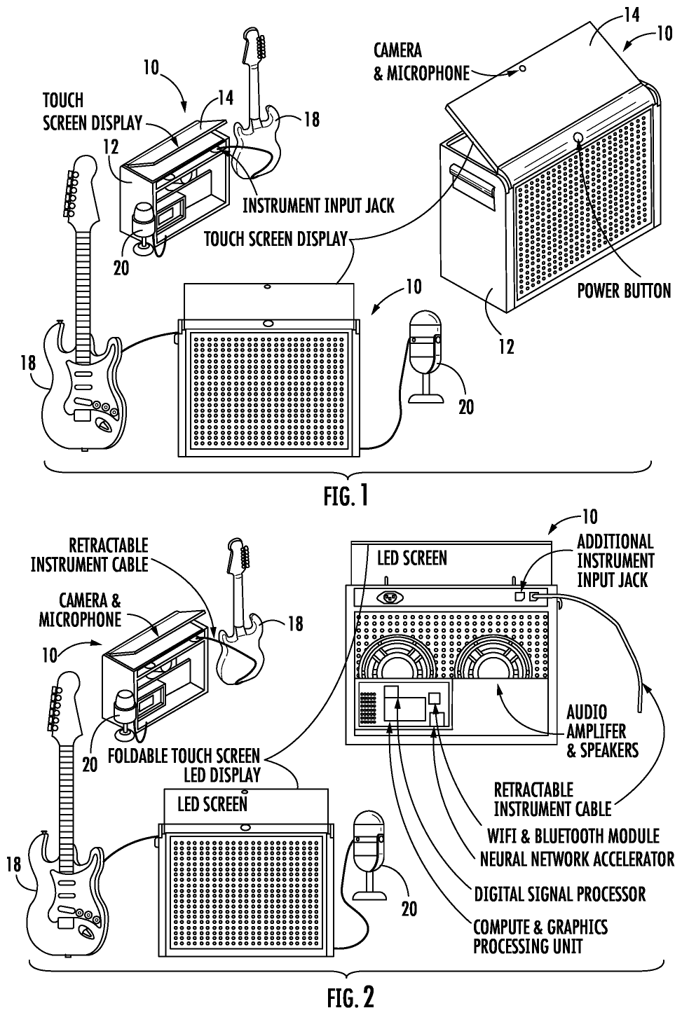

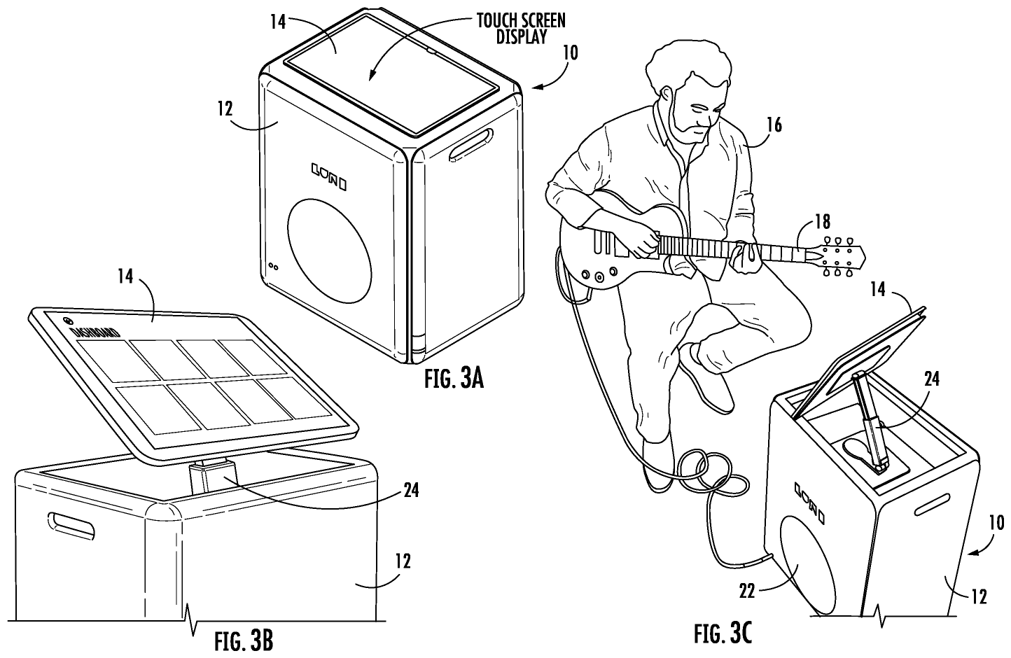

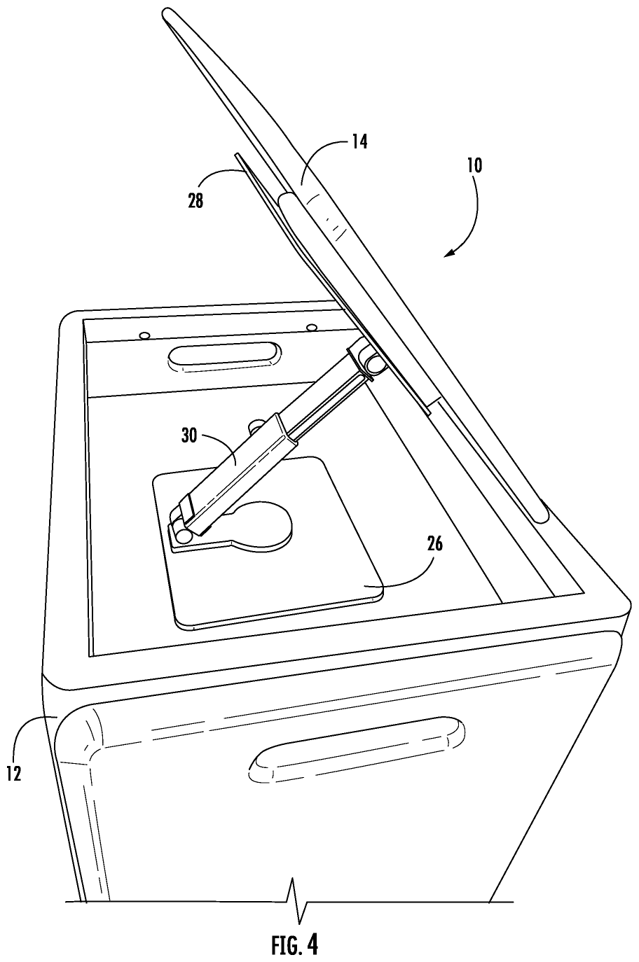

Referring now to FIGS. 1-4, shown therein is a digital audio system 10. The digital audio system 10 can include a primary housing 12 for holding the various components of the digital audio system 10 and a touch screen display 14 for allowing a musician 16 to enter and receive information from the digital audio system 10. The digital audio system 10 is designed to be used with musical instruments 18, such as guitars, keyboards, electric drumsets, and any other musical instrument that can be plugged into an amplifier. The digital audio system 10 can also be configured to interact with a microphone 20 and include a speaker 22 for delivering sound from the digital audio system 10. The touch screen display 14 can include a camera and microphone to capture audio and video. The microphone associated with the digital audio system 10 and/or the touch screen display 14 is a different microphone than the microphone 20 that is plugged into the digital audio system 10 for singing. The microphone of the digital audio system 10 and/or the touch screen display 14 is used for commands/voice inputs given to the digital audio system 10. The digital audio system 10 could also come with a predetermined number of retractable power cable and/or retractable audio cables to be able to connect to microphones 20 and/or instruments 18. The digital audio system 10 could also come with multiple audio inputs to accommodate multiple instruments. The digital audio system 10 could also come with an output jack for headphones and/or for routing sound output to another amplifier via a mono cable.

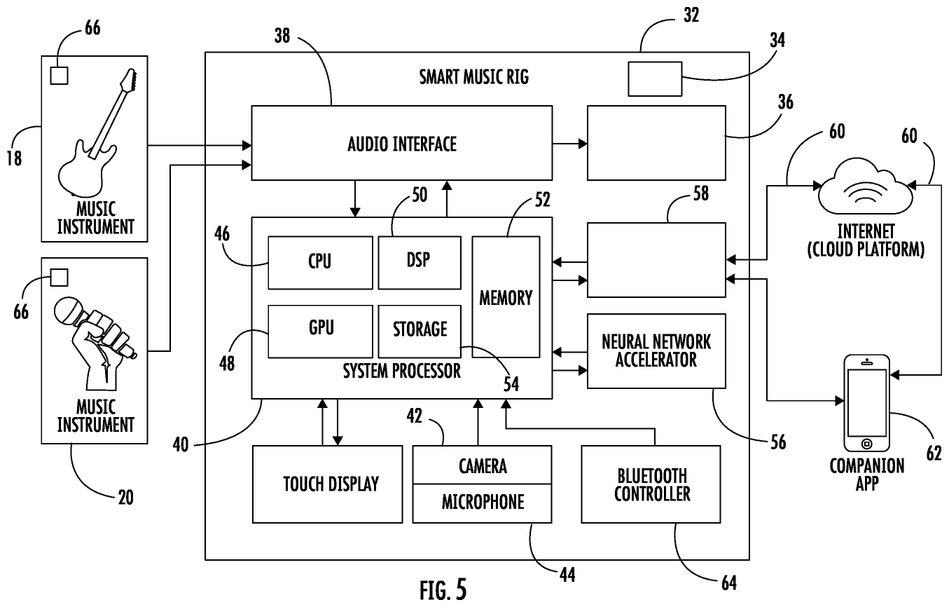

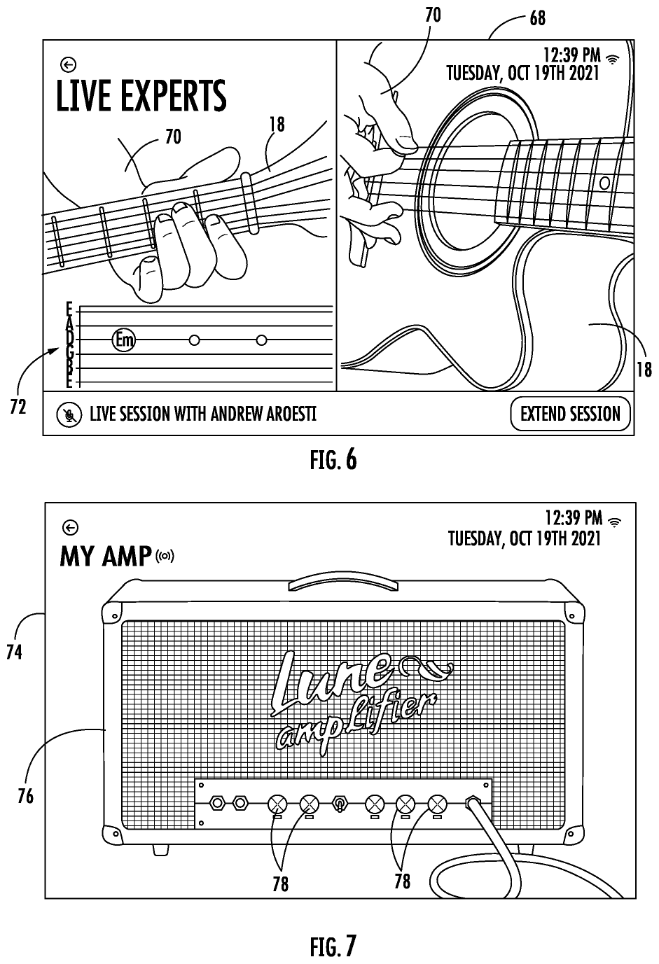

As shown in FIGS. 3A-4, the touch screen display 14 can be raised up, tilted and rotated relative to the primary housing 12 of the digital audio system 10. FIG. 4 shows a linkage assembly that provides the movement capabilities of the touch screen display 14 relative to the primary housing 12 of the digital audio system 10 and connects the two. The linkage assembly 24 can include a base portion 26 supported by the primary housing 12, a display support device 28 for attachment to the touch screen display 14 and a telescopic arm 30 extending between the base portion 26 and the display support device 28. The telescopic arm 30 can have a hinged relationship with the base portion 26 on one end and the display support device 28 on the other end. In one embodiment, the connection between the telescopic arm 30 and the base portion 26 can be rotatable to provide the rotational movement of the touch screen display 14 relative to the primary housing 12 of the digital audio system 10. In another embodiment, the connection between the telescopic arm 30 and the display support device 28 can be rotatable to provide the rotational movement of the touch screen display 14 relative to the primary housing 12 of the digital audio system 10. The tilting movement of the touch screen display 14 can be provided by the hinged relationship between the telescopic arm 30 and the display support device 28 (and thus the touch screen display 14) and/or the hinged relationship between the telescopic arm 30 and the base portion 26. The raising motion of the touch screen display 14 relative to the primary housing 12 can be provided by the telescopic arm 30 and/or the hinged relationships of the ends of the telescopic arm 30. It should be understood and appreciated that the linkage assembly 24 can have any componentry that permits the touch screen display 14 to be raised, tilted and/or rotated relative to the primary housing 12 of the digital audio system 10 so the touch screen display 14 can be interacted with by the user from any side of the digital audio system 10.

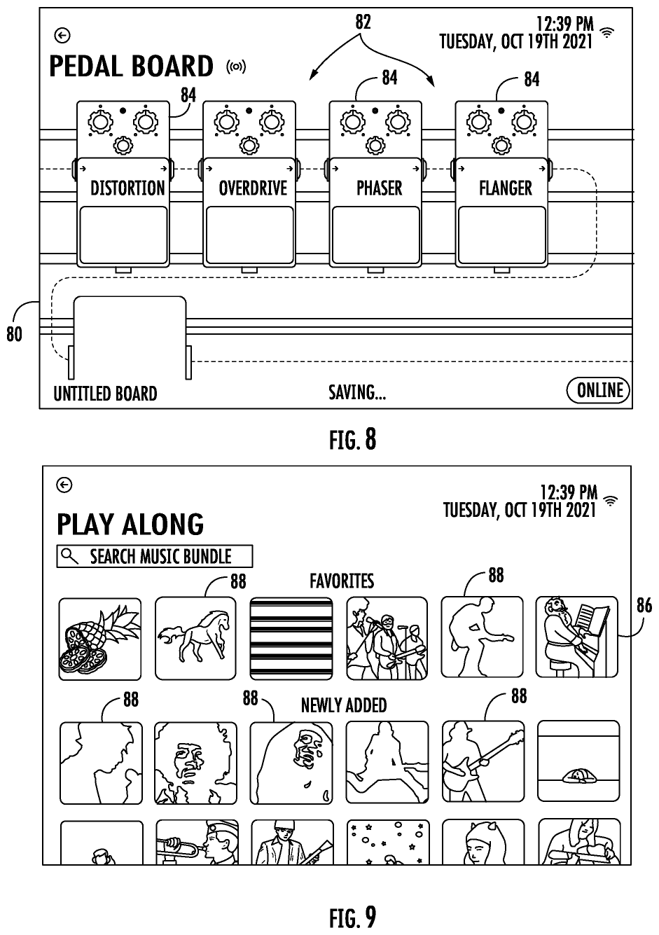

The digital audio system 10 can also include an audio control system 32 for managing the operations of the digital audio system 10. Referring now to FIG. 5, shown therein is an exemplary diagram of the audio control system 32 and what components it might can include. The audio control system 32 can include an amplifier 34 (or audio amplifier circuit) that converts the often barely audible or purely electronic signal of a musical instrument into a larger electronic signal to feed to a loudspeaker. A musical instrument such as an electric guitar, an electric bass, electric organ, synthesizers, drum machine, and more can be connected to the rig and the signals after being processed are sent to the audio amplifier circuit and the loudspeaker. The audio control system 32 can also include a speaker driver 36 to convert an electrical audio signal into a corresponding sound. This takes the input from the amplifier 34 and plays the audio signal on the speaker 22.

The audio control system 32 also provides the operational control of the touch screen display 14, which delivers the applications and the platform to allow musicians to learn, receive guidance and capture performances. The touch screen display 14 allows the musician to interact and utilize all the features of the digital audio system 10 including but not limited to, volume and gain control, effects and pedals, play along mode, multiplayer playback, video recording, creating music projects and more. The audio control system 32 can also include an audio interface 38 to take electrical input from a musical instrument and reroute the signal to a system processor 40. The audio interface 38 also converts the electrical signals into computer readable format at low latency. The interface 38 and the software are chosen for maximum performance and least latency. The interface 38 also allows rerouting multiple channels for multiple instruments.

The audio control system 32 can also be designed to control the operational aspects of a video camera 42 and a microphone 44 in the touch screen display 14. The camera 42 allows the musician to go live on a video conference to receive remote guidance or provide teaching assistance to other musicians. Furthermore it allows the audio control system 32 to capture performances, shows and snippets of the musician playing.

The system processor 40 is a companion computer/embedded system that is mounted inside the primary housing 12 of the digital audio system 10. The system processor 40 is used to process, including but not limited to, incoming audio signals, remove noise, add filters and loudness, execute effects and pedals, run a graphical user interface (GUI) and more. This consists of one or many multi-threaded central processing units (CPUs) 46 and graphical processing units (GPUs) 48 that allow executing audio and video processing algorithms in real time. This is also responsible for sending the final output signals to the amplifier 34. The onboard processors act as the central control unit for processing and coordinating between different units. The audio control system 32 can also include a digital signal processor (DSP) 50 to process audio in real time and at low latency. The DSP 50 can be a specialized microprocessor chip that is optimized for the operational needs for digital signal processing. The input signals are rerouted from the interface to the specialized chip on which various audio processing algorithms like FFT and more are executed. The DSP 50 chip is also used for image processing captured from the high definition video camera 42.

In an example implementation, a browser application, a compatibility engine applying one or more compatibility criteria, and other modules or programs may be embodied by instructions stored in memory 52 and/or the storage unit 54 and executed by the system processor 40. Further, local computing systems, remote data sources and/or services, and other associated logic represent firmware, hardware, and/or software, which may be configured to assist in scheduling a home showing. The audio control system 32 of the digital audio system 10 may be implemented using a general-purpose computer and specialized software (such as a server executing service software), a special purpose computing system and specialized software (such as a mobile device or network appliance executing service software), or other computing configurations. In addition, user requests, profiles and parameter data, agent profiles and parameter data, location data, parameter matching data, and other data may be stored in the memory 52 and/or the storage unit 54 and executed by the system processor 40.

The embodiments of the invention described herein are implemented as logical steps in one or more computer systems. The logical operations of the present invention are implemented (1) as a sequence of processor-implemented steps executed in one or more computer systems and (2) as interconnected machine or circuit modules within one or more computer systems. The implementation is a matter of choice, dependent on the performance requirements of the computer system implementing the invention. Accordingly, the logical operations making up the implementations of the invention described herein are referred to variously as operations, steps, objects, or modules. Furthermore, it should be understood that logical operations may be performed in any order, adding and omitting as desired, unless explicitly claimed otherwise or a specific order is inherently necessitated by the claim language.

Data storage and/or memory may be embodied by various types of storage, such as hard disk media, a storage array containing multiple storage devices, optical media, solid-state drive technology, ROM, RAM, and other technology. The operations may be implemented in firmware, software, hard-wired circuitry, gate array technology and other technologies, whether executed or assisted by a microprocessor, a microprocessor core, a microcontroller, special purpose circuitry, or other processing technologies. It should be understood that a write controller, a storage controller, data write circuitry, data read and recovery circuitry, a sorting module, and other functional modules of a data storage system may include or work in concert with a processor for processing processor-readable instructions for performing a system-implemented process.

For purposes of this description and meaning of the claims, the term “memory” (e.g., memory 52) means a tangible data storage device, including non-volatile memories (such as flash memory and the like) and volatile memories (such as dynamic random-access memory and the like). The computer instructions either permanently or temporarily reside in the memory, along with other information such as data, virtual mappings, operating systems, applications, and the like that are accessed by a computer processor to perform the desired functionality. The term “memory” or “storage medium” expressly does not include a transitory medium, such as a carrier signal, but the computer instructions can be transferred to the memory wirelessly.

In a further embodiment, the audio control system 32 includes a neural network accelerator 56 (or AI accelerator) to accelerate intelligence and machine learning applications. The neural network accelerator 56 runs deep learning intelligence algorithms to recognize, aid and improve playback of different genres of songs. The neural network accelerator 56 processes the audio in parallel and send out relevant data to the system processor 40 to take action. Some of the applications include, but are not limited to, prediction of notes, identify playback style and abilities, playback of synthetic instruments behind the main instrument, and more. The neural network accelerator 56 can identify strengths and weaknesses of the musicians 16 and provide feedback of the areas where the musician needs to practice. Or, the neural network accelerator 56 could provide music to the musician that plays to the musicians strengths.

The audio control system 32 can also include a communication interface 58 (or network interface) capable of connecting the audio control system 32 (and thus the digital audio system 10) to an enterprise network via the network link 60, through which the audio control system 32 can receive instructions and data embodied in a carrier wave. When used in a local area networking (LAN) environment, the audio control system 32 is connected (by wired connection or wirelessly) to a local network through the communication interface 58, which is one type of communications device. When used in a wide-area-networking (WAN) environment, the audio control system 32 typically includes a modem, a network adapter, or any other type of communications device for establishing communications over the wide-area network. In a networked environment, program modules depicted relative to the audio control system 32 or portions thereof may be stored in a remote memory storage device. It is appreciated that the network connections shown are examples of communications devices for and other means of establishing a communications link between the computers may be used. In another embodiment, the audio control system 32 can also be set up to have a wired connection to a computing device 62, such as a phone or tablet, to communicate with the computing device 62, or with an application on the computing device 62. The computing device 62 can also communicate with the audio control system 32 via a network (internet) and the wireless network link 60.

The audio control system 32 can also include a Bluetooth controller 64 that can communicate with a remote 66 that can be carried by the musician 16 or attached to the musical instrument 18 to provide the musician 16 a way to perform certain functions of the digital audio system 10. In one embodiment shown in, the remote 66 can be a rotary dial releasably connectable to a musical instrument that when rotated, can transition from predesigned audio settings. The remote 66 can include any and all electronic components to make it work with the audio control system 32. The remote 66 could also communicate with the digital audio system 10 communication interface 58 via the wireless network link 60. In some situations, the remote 66 can have a hardwired connection to the digital audio system 10.

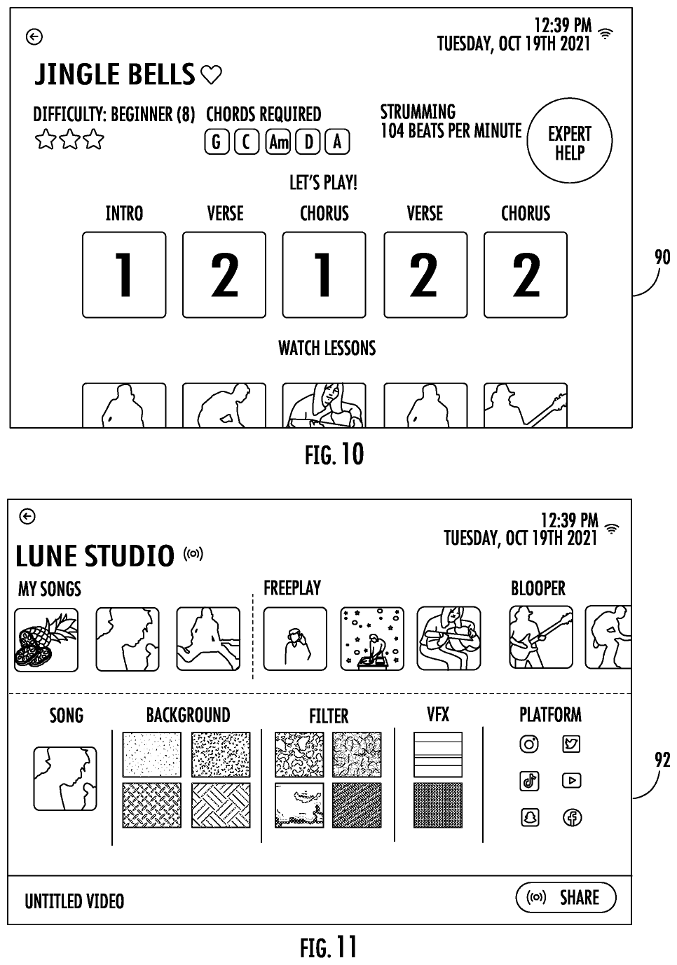

Referring now to FIGS. 6-11, shown therein are screenshots taken from the touch screen display 14 of the digital audio system 10. FIG. 6 is a student view screenshot 68 showing an instructor's hands 70 on the instrument 18 learning to be played. The student view screenshot 68 allow a learner or musician to connect with an instructor (either exclusively or as part of a virtual clinic) and take part in an interactive session with the instructor through the digital audio system 10 and online platform. The learner in this context will be able to communicate with the instructor (either directly if exclusive or via chat in a virtual clinic), listen to the instructors instrument as well as view/hear any AV recording that the instructor may enable as well as view any real time graphical representation of the music played to further assist learning. The screenshot 68 also shows a note section 72 depicting the note(s) being played by the instructor's hands 70. FIG. 7 is a screenshot 74 showing an amp 76 with various dials 78 that can be adjusted via interaction with the touch screen display 14. This permits the user of the digital audio system 10 to set up and adjust the digital audio system 10 as a musician might do for an amplifier in the past. FIG. 8 is a screenshot 80 showing an pedal board 82 that can be manipulated by interaction with the touch screen display 14 to provide the user control of the sounds, presets and levels simultaneously with their foot while performing with the digital audio system 10. The screenshot 80 also shows various pedals 84 that correspond to a particular audio feature, such as distortion, overdrive, phaser, flanger, etc. The digital audio system 10 also permits a user the ability to setup customized pedal board setups to be recalled later when desired.

FIG. 9 is a screenshot 86 that depicts the digital audio system's 10 ability to provide numerous songs or audio arrangements to select to play along with. The screenshot 86 includes numerous thumbnails 88 of the various songs or audio arrangements a user can select. FIG. 10 is a song screenshot 90 that depicts one example of the user interface and wireframes of how a song is broken down into simpler chunks including but not limited to intro, verse, chorus and more. These chunks help the user to easily learn and master a section of the song. The numbers are assigned to each chunk to represent complexity and skill level. The screen 90 also allows the user to request for expert help on the selected song. FIG. 11 is a screenshot 92 that depicts one example of the user interface and wireframes of the creator studio. The creator studio allows users to quickly craft videos with effects and filters that are ready to be shared on various social media platforms. Users can use their previously recorded videos or even their freeplay sessions to craft snippets for social media. The user can select various filters, backgrounds, effects, etc via the screenshot 92 viewable on the touch screen display 14.

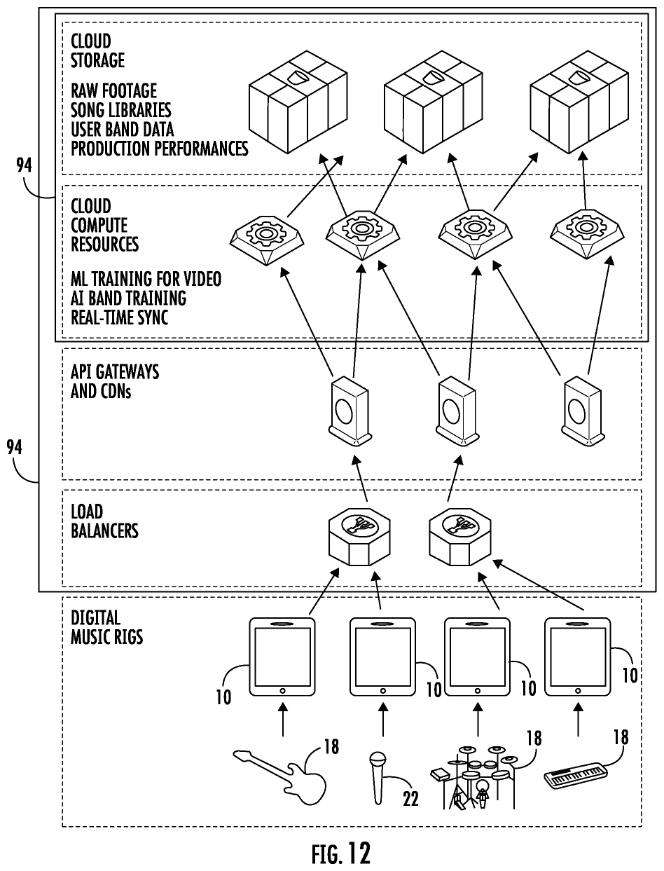

FIG. 12 is a block schematic diagram showing a cloud connected system 96 according to the disclosure. The architecture is an overview of a cloud platform for the digital audio system 10.

The digital audio system 10 is connected to a central cloud infrastructure 94 that provides software and content updates to the digital audio system 10. The digital audio systems 10 can interface with the cloud infrastructure 94 using different networking protocols including but not limited to REST, HTTP 1.0/2.0 or Websockets and more. The cloud infrastructure 94 is distributed across the globe and the digital audio systems 10 can download and upload content to the nearest servers. This helps scaling to millions of digital audio systems 10.

Content generated from the digital audio system 10, including video and audio, can be uploaded to the cloud for the user to access and store for future use. In addition, the cloud infrastructure 94 provides compute resources to train Machine Learning (ML) algorithms for virtual bands, understanding user preferences and recommendations. The ML algorithms are also applied to video recorded from the music rigs, with permission from the user, to generate highlights and key clips from their performances. These clips are auto clipped and stitched together to create shareable content for the user. Using advanced ML techniques the digital audio system 10 can capture and stitch together the best parts of a user's sessions. In certain embodiments the camera is paired with a microphone to record audio from everything but the instruments.

The audio control system 32 of the digital audio system 10 permits the digital audio system 10 to perform numerous functions. The following is an exemplary list of functions the digital audio system 10 is able to perform:
Allows music instructors and teachers to connect with users either one on one or as a class to provide live or archived musical training sessions via audio, video or interactive 3D graphics.
Allows users to access archived classes or live music training output as video, audio and 3D visualization.
Allows users to refresh and update music content library remotely that is displayed on the touch screen display 14 associated with the digital audio system 10 over the computer network.
Allows users to receive feedback on their playing during a live training session by the instructor in the form of audio, video or 3D interactive graphics sent directly to the accompanied audio control system 32 and touch screen display 14 associated with the digital audio system 10.
Allows real time performance metrics for a user to be sent to the instructor on the user's playing during a live training session in the form of audio, visual or 3D interactive graphics sent directly to the audio control system 32 and touch screen display 14 associated with the digital audio system 10.
The digital audio system 10 can mimic tones for specific instruments only by using a media clipping of the tone (for example, from a YouTube video, or mp3 file of the song). Using machine learning to figure out what is being played and the effective impulse response for the sound profile that is being heard.
Allows the digital audio system 10 to capture a live performance through any multimedia capturing device such as, but not limited to, a camera, musical instrument input, audio recording, and convert them into interactive music lessons consisting of, but not limited to, audio, video and graphical visualizations. The digital audio system 10 can also process the videos by using preset templates, filters and/or effects.
The digital audio system 10 can record line input and/or video (and synchronize them into one video) from user jam sessions/performances and create shows and performance pieces that can be shared on social media directly.
The digital audio system 10 can capture a live performance through any multimedia capturing device such as, but not limited to, a camera, musical instrument input, audio recording, and convert them into sharable content by adding templates, filters, visual effects, etc.
The digital audio system 10 can synchronize entire sound profiles between two or more digital audio systems 10 simply by sharing a sound profile (volume, tone, pedals, cabinet and amp) either via a peer to peer communication between digital audio systems 10, broadcast communication between digital audio systems 10 and/or as digital assets that could be purchased.
The digital audio system 10 can capture sound profiles of specific instruments from the audio of a video, or an audio file, using machine learning and can break down a song into components by difficulty and completeness of the idea. This further extends to means to correlate different songs along with the users preferences and skill level for a personalized learning library.
The digital audio system 10 can use the neural network accelerator 56 to generate music intune with the user (just as a human bandmate would).

The present disclosure is also directed to certain features and functions made possible by the cloud connected system 96. The cloud connected system 96 provides a platform for the following features and functionality:
Ability to connect one or digital audio systems 10 together through a network such that the users can play on their respective digital audio systems 10 as though they were part of a live band.
Able to capture video of a performance using the camera 42 and the input audio (through instrument and/or mic) simultaneously and synchronize the captured video and input audio into one single video wherein the input audio (through instrument) and the microphone audio (captured as part of the video itself) are completely in sync with the video. Furthermore, the video can be slowed down or sped up as necessary to keep the synchronizations corresponding.
Sound profiles as presets can be shared across digital audio systems 10. A user is able to save a sound profile as a preset and share it as is in a digital asset marketplace. Furthermore, while in the learning side of the platform, the specified sound preset is applied for the specific song that is being learned. Sound profiles may also be saved on a song basis so that you can always sound like the song you want to play.
Users will be able to create Artificially intelligent avatars playing different instruments as their band mates. Skins and accessories for the bandmates can be bought on the platform itself. The Al bandmates can play backing tracks of songs, create backing tunes over which the user can play any part of the band. The Al bandmates use machine learning algorithms that adapt to the users tempo and key in live play and the users general skill level and playing style at a high level.
Users will be able to connect to vetted instructors on the other end through their digital audio system 10. The digital audio system 10 can enable the transmission of audio, video and instrument line input from the user to the instructor and vice versa. The user may use instant experts to quickly get their questions cleared.
Student view—Live Music Sessions allow a learner or musician to connect with an instructor (either exclusively or as part of a virtual clinic) and take part in an interactive session with the instructor through the cloud connected system 96 and online platform. The learner in this context will be able to communicate with the instructor (either directly if exclusive or via chat in a virtual clinic), listen to the instructors instrument as well as view/hear any AV recording that the instructor may enable as well as view any real time graphical representation of the music played to further assist learning.
Live Music Sessions empower an instructor of music to be able to hold virtual music clinics and/or one on one private music tutoring sessions. The Instructor will be able to enable microphone/camera access, enabling access from the input of their instrument. As the instructor interacts with the class in real time, the cloud connected system 96 algorithms will provide friendly representations of the notes played by the instructor. The instructor will also be able to observe aggregate metrics of the student(s) they are engaged with and communicate with them (either directly if exclusive or via chat in a virtual clinic) to provide further support and motivation. The instructors will be able to set a time based rate for the services offered.
Users of the platform will also be able to access carefully curated, archived music sessions created by vetted instructors of music on various topics of choice. The users may also request content that content creators would be aware of. The archived music session may contain video/audio as enabled by the instructor with the ability to access different views (for example, left hand, right hand) along with the instructors' line inputs (which would be independently volume controllable). The entire lesson/session would be aided by real time graphical representations of the music played.
Lesson creator studio will be accessible to users with instructor accounts. All Instructors will go through a vetting process. Lesson creator studio would be a service extended by the online platform for instructors to swiftly and effectively utilize their time to create educational Music content. The manifestation of the cloud connected system 96 on the digital audio system 10 would allow an instructor to record video, audio and the direct line input from their instrument(s). Al algorithms would convert these inputs into several views relevant to the instrument, graphical representations of the music played for ease of understanding. Once the instructor is done, they will have the ability to structure the raw inputs as well as generated processed inputs to their liking and instantly share on the online platform as an archived session.
Along with the users of the cloud connected system 96 and the digital audio system 10, people also have the option to sign up on the platform as an instructor. Instructors will be vetted and tiered to meet the standards set forth by the cloud connected system 96. Instructors will be able to provide lessons, sessions and clinics on the platform in addition to using the platform as a regular user. Instructors may charge other users for their time/content.
The cloud connected system 96 can provide a virtual music room. The virtual music room is an extension of the platform that enables users to connect with each other. The user may be able to interact with the Virtual Music Room on the platform through the digital audio system 10, phone, computer, VR headset and any new interfaces which may be developed in the future. The Virtual Music Room is meant to be a space where users may be able to connect and chat/talk/jam with others at their same level. The platform tries to ensure that the other users in your room are at the same level as you based on how/what you play. Privacy would be maintained in the way it is done in anonymous chat systems. Users can chat with other users, jam with them through their digital audio systems 10 with consent from the other user.

Additional features of the present disclosure are as follows:
To make you feel like a star. Capture your performances using the inbuilt camera and line input. The system will render a video in real time with synchronized output of video and input audio. The system will be able to apply real time filters to the rendered video such as a background of a concert stadium. This concept extends further into VR as well.
The social platform would serve as a market for the buy and sale of digital assets related to the music rigs. This could manifest as skins, presets, video backgrounds and filters.
The share studio enables users to view all recordings of their past performances where the video and line audio are synchronized. Users will have the ability to choose from a list of templates a format for their video, add in filters and effects and instantly be able to share a studio quality music video to the lune platform and any other social media of their choice.
On a per song basis, provide educational content, amplifier preset & pedal configuration, the backing band, the chord sheet, finger colors/numbers and additional aids by which the user will be able to learn and play the song.
Each user will have a personalized learning library that will prioritize songs to learn by the users skill level, preference and song style and difficulty. Each song will come with its own learning bundle complete for the user to learn, play and share the performance of the song.

From the above description, it is clear that the present disclosure is well adapted to carry out the objectives and to attain the advantages mentioned herein as well as those inherent in the disclosure. While presently preferred embodiments have been described herein, it will be understood that numerous changes may be made which will readily suggest themselves to those skilled in the art and which are accomplished within the spirit of the disclosure and claims.

What is claimed is:

1. A portable digital audio system for a musician, the digital audio system comprising:
an amplifier for processing an audio signal from a musical instrument or microphone electronically connected to the digital audio system;
a speaker for playing a sound associated with the audio signal processed by the amplifier;
an audio control system providing operational control of the digital audio system;
a primary housing for supporting the amplifier, the audio control system, and the speaker; and
a touch screen display in electronic communication with the audio control system and supported by the primary housing.

2. The digital audio system of claim 1 further comprising a linkage assembly connected to the primary housing of the digital audio system and the touch screen display.

3. The digital audio system of claim 2 wherein the linkage assembly allows the touch screen display to be able to be extended away from the primary housing of the digital audio system, tilted relative to the primary housing and rotated relative to the primary housing.

4. The digital audio system of claim 1 further comprising a camera and microphone to capture audio and video of a musician playing a musical instrument.

5. The digital audio system of claim 1 wherein the audio control system includes a neural network accelerator to determine strengths and weaknesses of the musician based on audio and/or visual data captured by the digital audio system.

6. The digital audio system of claim 5 wherein the audio control system recommends musical content to the musician to play based upon the weaknesses and strengths of the musician determined by the neural network accelerator.

7. The digital audio system of claim 1 further comprising a Bluetooth remote device releasably securable to the musical instrument that can communicate with a Bluetooth controller of the audio control system to affect certain audio functions of the digital audio system.

8. The digital audio system of claim 1 wherein the audio control system provides a digital pedal board to be displayed on the touch screen display wherein individual pedals can be adjusted to create a desired sound effect.

9. The digital audio system of claim 1 wherein the audio control system provides instructional videos on the touch screen display from music instructors showing specific a hand placement on an instrument for playing a particular song or note.

10. The digital audio system of claim 1 wherein the audio control system provides a digital amplifier to be displayed on the touch screen display wherein individual audio adjustment knobs can be adjusted to create a desired sound effect.

11. The digital audio system of claim 1 further comprising retractable audio cords for connection to instruments or microphones.

12. The digital audio system of claim 1 wherein the audio control system provides a studio option where a musician can record their playing of an instrument to create a video.

13. The digital audio system of claim 12 wherein audio control system provides the user an ability to add various effects to the video created.

14. The digital audio system of claim 1 wherein the digital audio system can be in communication with a cloud connected system with other digital audio systems.

15. The digital audio system of claim 14 wherein a music instructor can be on a first digital audio system and a music student can be on a second digital audio system and the music instructor can use the first digital audio system to teach the music student in real time a music lesson via the first and second digital audio system's communication through the cloud connected system.

16. The digital audio system of claim 14 wherein multiple musicians can be on separate digital audio systems to synchronize each of the musicians' video performance via the cloud connected system.

17. The digital audio system of claim 1 further comprising a first audio output to link the digital audio system to other speakers via an audio cable.

18. The digital audio system of claim 1 further comprising a second audio output for headphones to be connected via an audio cable.
